(19) United States
(12) Patent Application Publication
(10) Pub. No.: US 2018/0012999 A1
(43) Pub. Date: Jan. 11, 2018

(54) SEMICONDUCTOR DEVICE AND ELECTRONIC APPARATUS

(71) Applicant: FUJITSU LIMITED, Kawasaki-shi (JP)

(72) Inventors: Hiroko Tashiro, Ashigarakami (JP); Hideki Kitada, Atsugi (JP)

(73) Assignee: FUJITSU LIMITED, Kawasaki-shi (JP)

(21) Appl. No.: 15/612,253

(22) Filed: Jun. 2, 2017

(30) Foreign Application Priority Data
Jul. 7, 2016 (JP) 2016-134713

(51) Int. Cl. H01L 29/78; H01L 27/092; H01L 27/02; H01L 29/06; H01L 23/535

(52) U.S. Cl. CPC H01L 29/7849; H01L 29/0649; H01L 29/0607; H01L 23/535; H01L 27/0207; H01L 27/092

(57) ABSTRACT

A semiconductor device includes a via and first and second transistors of the same channel type which are formed in a semiconductor substrate. The first and second transistors are located in a first lateral direction of the via and have their channel direction that matches the first lateral direction. A first stress relaxation region is formed in the semiconductor substrate between the via and the first transistor which is located closer to the via than the second transistor is. A second stress relaxation region smaller than the first stress relaxation region is formed in the semiconductor substrate between the first transistor and the second transistor which is located farther from the via than the first transistor is.

### CROSS-REFERENCE TO RELATED APPLICATION

This application is based upon and claims the benefit of priority of the prior Japanese Patent Application No. 2016-134713, filed on Jul. 7, 2016, the entire contents of which are incorporated herein by reference.

### FIELD

The embodiments discussed herein relate to a semiconductor device and an electronic apparatus.

### BACKGROUND

In the field of semiconductor devices, there is a known technique in which conductors called through-silicon vias (TSVs) are formed. These TSVs are formed to run through a semiconductor substrate in which semiconductor elements such as transistors are formed. By stacking a group of semiconductor devices including TSVs and electrically connecting the semiconductor devices with the TSVs, a three-dimensional (3D) integrated circuit is realized (see Japanese Laid-open Patent Publication No. 2011-040457, for example).

When a TSV is formed in a semiconductor substrate, stress is generated around the TSV. When a group of transistors are arranged around such a TSV, the stress around the TSV affects an individual transistor differently, depending on the configuration of the individual transistor and the positional relationship between the individual transistor and the TSV. For example, even if the group of transistors have the same configuration, when these transistors are arranged side by side in a lateral direction of the TSV, an individual transistor exhibits different characteristics, depending on the distance from the TSV.

### SUMMARY

According to one aspect, there is provided a semiconductor device including: a semiconductor substrate; a via formed in the semiconductor substrate; a first transistor of a first channel type which is formed in the semiconductor substrate, which is located in a first lateral direction of the via, and whose channel direction matches the first lateral direction; a second transistor of the first channel type which is formed in the semiconductor substrate, which is located in the first lateral direction of the via and next to the first transistor sandwiched between the second transistor and the via, and whose channel direction matches the first lateral direction; a first stress relaxation region which is formed in the semiconductor substrate and which is located between the via and the first transistor; and a second stress relaxation region which is formed in the semiconductor substrate, which is located between the first and second transistors, and which is smaller than the first stress relaxation region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a semiconductor device according to a first embodiment;

FIGS. 2A and 2B illustrate stress and characteristics of transistors;

FIG. 3 illustrates examples of a relationship between the width of a stress relaxation region and a current that flows through an nMOS according to the first embodiment;

FIG. 4 illustrates examples of a relationship between the width of a stress relaxation region and a current that flows through a pMOS according to the first embodiment;

FIGS. 5A and 5B illustrate area penalties;

FIG. 6 illustrates a first example of the semiconductor device according to the first embodiment;

FIG. 7 illustrates a second example of the semiconductor device according to the first embodiment;

FIGS. 8A and 8B illustrate a third example of the semiconductor device according to the first embodiment;

FIGS. 9 and 10 illustrate an example of a semiconductor device according to a second embodiment;

FIG. 11 illustrates an example of characteristics of transistors of the semiconductor device according to the second embodiment;

FIG. 12 illustrates another example of the semiconductor device according to the second embodiment;

FIGS. 13 and 14 illustrate an example of a semiconductor device according to a third embodiment;

FIG. 15 illustrates an example of a semiconductor device according to a fourth embodiment;

FIG. 16 illustrates an example of a method of setting the width of a stress relaxation region according to a fifth embodiment;

FIG. 17 illustrates an example of a semiconductor device according to a sixth embodiment;

FIG. 18 illustrates an example of a semiconductor device according to a seventh embodiment; and

FIG. 19 illustrates an example of an electronic apparatus according to an eighth embodiment.

### DESCRIPTION OF EMBODIMENTS

Hereinafter, embodiments will be described with reference to the accompanying drawings, wherein like reference characters refer to like elements throughout.

First, a first embodiment will be described.

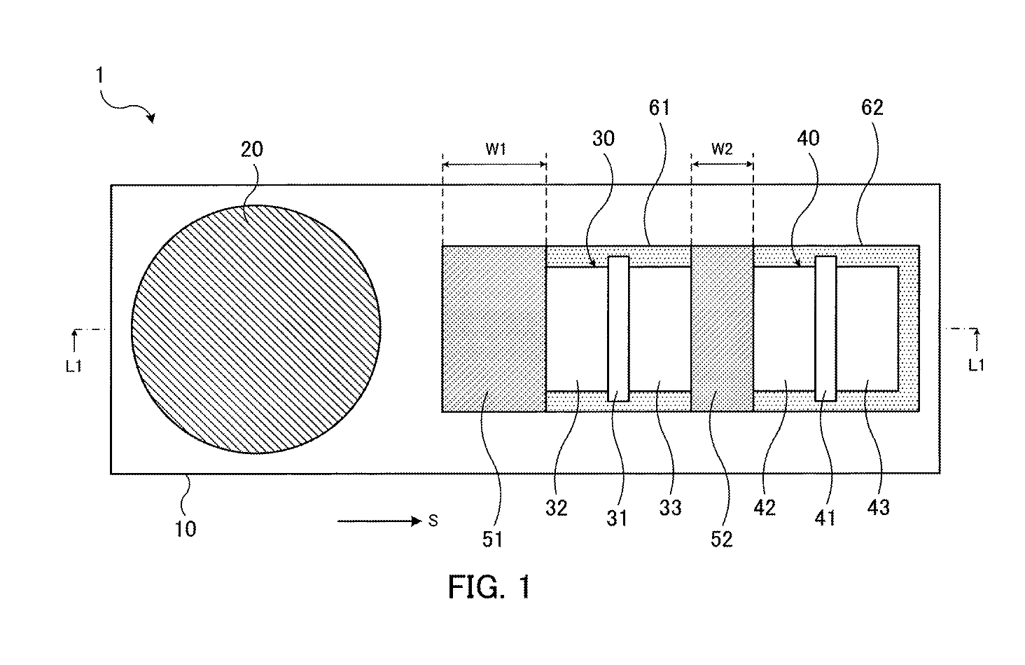

FIG. 1 illustrates an example of a semiconductor device according to a first embodiment. More specifically, FIG. 1 is a schematic plan view illustrating a main portion of an example of a semiconductor device 1 according to the first embodiment.

The semiconductor device 1 illustrated in FIG. 1 includes a semiconductor substrate 10, a via 20, and a group of transistors (two transistors 30 and 40 in FIG. 1 as an example).

The semiconductor substrate 10 is a silicon (Si) substrate, for example. Alternatively, a substrate made of germanium (Ge), silicon germanium (SiGe), gallium arsenide (GaAs), indium phosphide (InP), or the like may be used as the semiconductor substrate 10.

For example, the via 20 is formed to run through the semiconductor substrate 10. The via 20 is referred to as a TSV, for example. One of various kinds of conductor material may be used for the via 20. For example, metal material such as copper (Cu) may be used for the via 20. While not illustrated, an insulating film made of silicon oxide (SiO) or the like is formed at the interface between the via 20 and the semiconductor substrate 10. Namely, the via 20 and the semiconductor substrate 10 are insulated from each other by the insulating film. The planar (cross-section) shape of the via 20 is not limited to a circle as illustrated as an example in FIG. 1.

The transistors 30 and 40 are formed side by side in a lateral direction S of the via 20. The transistor 40 is located further from the via 20 than the transistor 30 is. The transistors 30 and 40 are metal-oxide-semiconductor field-effect transistors (MOSFETs), for example.

The transistor 30 includes a gate electrode 31 formed on the semiconductor substrate 10 and a source region 32 and a drain region 33 formed in the semiconductor substrate 10 on both sides of the gate electrode 31. The transistor 30 is formed in the semiconductor substrate 10 such that the channel direction (gate length direction) of the transistor 30 matches the lateral direction S of the via 20 (the direction in which the transistors 30 and 40 are formed side by side).

Likewise, the transistor 40 includes a gate electrode 41 formed on the semiconductor substrate 10 and a source region 42 and a drain region 43 formed in the semiconductor substrate 10 on both sides of the gate electrode 41. The transistor 40 is formed in the semiconductor substrate 10 such that the channel direction (gate length direction) of the transistor 40 matches the lateral direction S of the via 20 (the direction in which the transistors 30 and 40 are formed side by side).

The transistors 30 and 40 have the same channel type. Namely, both the transistors 30 and 40 are formed to function as n-channel-type MOS transistors (nMOSs) or p-channel MOS transistors (pMOSs).

When a silicon substrate is used as the semiconductor substrate 10, the crystal face of the silicon substrate in the channel direction in which the transistors 30 and 40 are formed is the (001) or (110) face, for example. On the (001) face, electrons, which are the carriers in an nMOS, may obtain a relatively high mobility. On the (110) face, holes, which are the carriers in a pMOS, may obtain a relatively high mobility.

A stress relaxation region 51 is formed of predetermined insulating material in the semiconductor substrate 10 between the via 20 and the transistor 30, which is located closer to the via 20 than the transistor 40 is. In addition, a stress relaxation region 52 is formed of predetermined insulating material in the semiconductor substrate 10 between the transistor 30 and the transistor 40, which is located farther from the via 20 than the transistor 30 is. The stress relaxation region 51 formed between the via 20 and the transistor 30 is larger than the stress relaxation region 52 formed between the transistors 30 and 40. FIG. 1 illustrates, as an example, the semiconductor device 1 including the stress relaxation region 51 having a width W1 larger than a width W2 of the stress relaxation region 52 in the direction S.

The stress relaxation regions 51 and 52 function to relax the stress that is generated by the formation of the via 20 in the semiconductor substrate 10 in the transistors 30 and 40. How the stress relaxation regions 51 and 52 relax the stress generated by the formation of the via 20 will be described below.

The transistor 30 is formed at a region (active region) demarcated by the stress relaxation regions 51 and 52 and an element isolation region 61. The transistor 40 is formed at a region (active region) demarcated by the stress relaxation region 52 and an element isolation region 62.

In the semiconductor device 1, for example, a part of the element isolation region 61 formed to surround the transistor 30 is used as the stress relaxation region 51. Alternatively, a part of the element isolation region 61 formed to surround the transistor 30 and an insulating region formed of predetermined insulating material outside the part may be used as the stress relaxation region 51.

Alternatively, in the semiconductor device 1, for example, a part of the element isolation region 61 formed to surround the transistor 30 and a part of the element isolation region 62 formed to surround the transistor 40 may be used as the stress relaxation region 52. Alternatively, a part of the element isolation region 61 formed to surround the transistor 30, a part of the element isolation region 62 formed to surround the transistor 40, and an insulating region formed of predetermined insulating material between these parts may be used as the stress relaxation region 52.

The stress relaxation regions 51 and 52 and the element isolation regions 61 and 62 are formed in the semiconductor substrate 10 by using a shallow trench isolation (STI) method, for example. For the stress relaxation regions 51 and 52, insulating material such as a compound of silicon (Si) with one or more elements such as oxygen (O), nitrogen (N), or carbon (C) is used. Namely, for the stress relaxation regions 51 and 52, silicon oxide (SiO), silicon nitride (SiN), silicon oxycarbide (SiOC), silicon carbonitride (SiCN), or the like is used. For the element isolation regions 61 and 62, insulating material such as silicon oxide (SiO) is used.

The stress relaxation regions 51 and 52 and the element isolation regions 61 and 62 may be formed in the semiconductor substrate 10 by using local oxidation of silicon (LOCOS), depending on the insulating material used for the above regions and the material for the semiconductor substrate 10.

The semiconductor device 1 is provided with at least one wiring layer (not illustrated) formed on the semiconductor substrate 10 in which the transistors 30 and 40, etc. as described above are formed. The via 20 runs through the semiconductor substrate 10 and is connected to predetermined conductors (wirings, vias, etc.) in the wiring layer formed on the semiconductor substrate 10.

Next, the stress relaxation function of the stress relaxation regions 51 and 52 of the semiconductor device 1 will be described.

First, the stress that is generated by the formation of the via 20 in the transistors 30 and 40 and how this stress affects characteristics of the transistors 30 and 40 will be described, by using as an example a semiconductor device that does not include the stress relaxation regions 51 and 52.

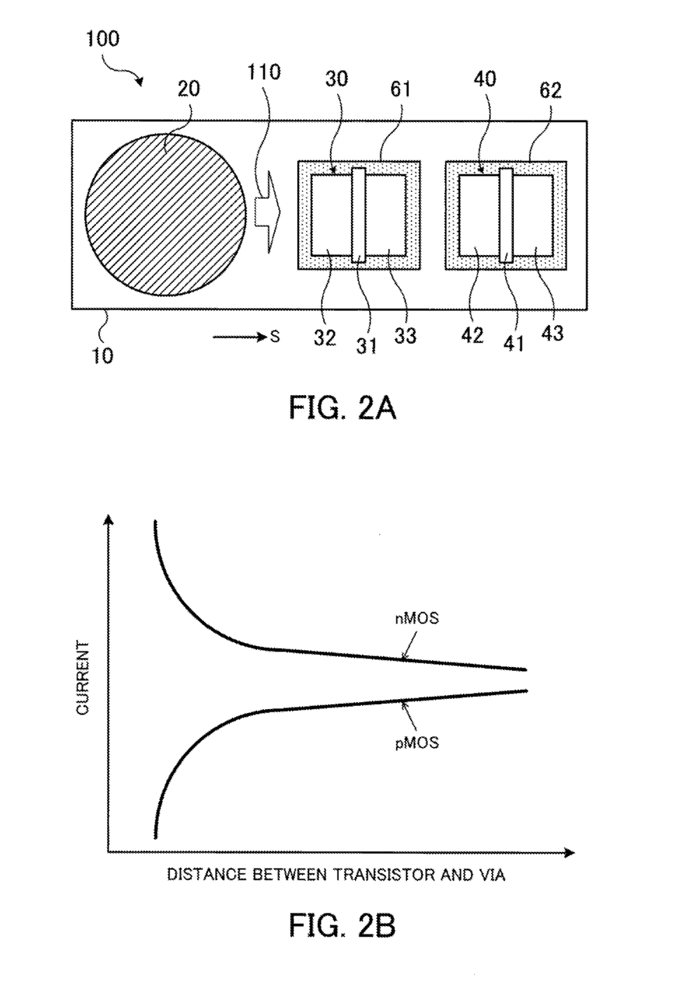

FIGS. 2A and 2B illustrate stress and characteristics of transistors. More specifically, FIG. 2A is a schematic plan view illustrating a main portion of an example of a semiconductor device 100. In addition, FIG. 2B schematically illustrates a relationship between the distance between an individual transistor and a via and a current flowing through the transistor.

The semiconductor device 100 illustrated in FIG. 2A includes a transistor 30 surrounded by an element isolation region 61 and a transistor 40 surrounded by an element isolation region 62. The transistors 30 and 40 have the same configuration. These transistors 30 and 40 are formed side by side in a lateral direction S of a via 20, and the channel directions of the transistors 30 and 40 match the direction S. The element isolation regions 61 and 62 of the semiconductor device 100 also have the same configuration (the same width and the same depth). The semiconductor device 100 differs from the above semiconductor device 1 in that the semiconductor device 100 does not include the above stress relaxation regions 51 and 52.

The element isolation region 61 around the transistor 30 generates compressive stress in the transistor 30. The larger the element isolation region 61 is, the larger the compressive stress will be. Likewise, the element isolation region 62 around the transistor 40 generates compressive stress in the transistor 40. The larger the element isolation region 62 is, the larger the compressive stress will be. When the element isolation regions 61 and 62 have the same configuration, the element isolation regions 61 and 62 generate approximately the same compressive stress in the transistors 30 and 40, respectively.

When the via 20 is formed in the semiconductor substrate 10 including the element isolation regions 61 and 62 and the transistors 30 and 40, stress is generated around the via 20. This stress remains in the semiconductor substrate 10 after the via 20 is formed. In another case, stress is generated when the via 20 and the semiconductor substrate 10 are expanded and contracted by the heat generated while the semiconductor device 100 is manufactured or operated, for example.

The following description assumes that the semiconductor device 100 illustrated in FIG. 2A has stress 110 (thick arrow) generated from the via 20 in the direction S. In this case, the direction of the stress 110 generated from the via 20 matches the channel directions of the transistors 30 and 40. In this state, tensile stress is generated in a channel region between a source region 32 and a drain region 33 of the transistor 30 and in a channel region between a source region 42 and a drain region 43 of the transistor 40. The tensile stress generated in the channel region of the transistor 30 closer to the via 20 is larger than the tensile stress generated in the channel region of the transistor 40 farther from the via 20.

FIG. 2B illustrates a relationship between the distance between an individual transistor (an nMOS and a pMOS) and a via and a current flowing through the transistor. In the case of an nMOS, when the nMOS is closer to the via, namely, when the tensile stress generated in the channel region is larger, a larger current tends to flow through the nMOS. This is because, in the case of an nMOS, the mobility of carrier electrons is increased with the tensile stress and is decreased with the compressive stress. In contrast, in the case of a pMOS, when the pMOS is closer to the via, namely, when the tensile stress generated in the channel region is larger, a smaller current tends to flow through the pMOS. This is because, in the case of a pMOS, the mobility of carrier holes is increased with the compressive stress and is decreased with the tensile stress.

With the configuration in FIG. 2A, when both of the transistors 30 and 40 are n-channel-type (nMOS) transistors, as seen from FIG. 2B, a larger current flows through the transistor 30 closer to the via 20, and a smaller current flows through the transistor 40 farther from the via 20. In contrast, when both of the transistors 30 and 40 are p-channel-type (pMOS) transistors, as seen from FIG. 2B, a smaller current flows through the transistor 30 closer to the via 20, and a larger current flows through the transistor 40 farther from the via 20.

Thus, even when the transistors 30 and 40 of the semiconductor device 100 illustrated in FIG. 2A have the same configuration, these transistors 30 and 40 could exhibit different characteristics, depending on the distance from the via 20 formed in the semiconductor substrate 10 and the stress that varies with the distance.

If the transistors 30 and 40 of the semiconductor device 100 are formed sufficiently away from the via 20, the impact of the tensile stress generated from the via 20 may be reduced, and the difference between the characteristics of the transistors 30 and 40 may be controlled. It means, however, that transistors fail to be formed near the via 20 in the semiconductor substrate 10. Namely, since the semiconductor device 100 has a smaller area (effective element area) in which transistors are allowed to be formed, further integration is prevented. Thus, an area penalty problem arises.

In contrast, the above semiconductor device 1 illustrated in FIG. 1 includes the stress relaxation region 51 having the width W1 between the via 20 and the transistor 30 closer to the via 20 and the stress relaxation region 52 having the narrower width W2 between the transistor 30 and the transistor 40 farther from the via 20.

In the semiconductor device 1, the stress relaxation region 51 functions as a part of the element isolation region that demarcates the transistor 30, and the stress relaxation region 52 functions as a part of the element isolation region that demarcates the transistors 30 and 40.

By increasing the widths W1 and W2 of the stress relaxation regions 51 and 52, the compressive stress generated in the transistor 30 and the compressive stress generated in the transistor 40 are increased. In this case, the transistor 30 adjacent to the stress relaxation region having the wider width W1 has a larger compressive stress increase effect than the transistor 40 adjacent to the stress relaxation region 52 having the narrower width W2.

By forming the stress relaxation regions 51 and 52 having predetermined sizes, respectively, the tensile stress generated by the formation of the via 20 in the transistors 30 and 40 is relaxed. In this case, the transistor 30 having a larger compressive stress increase effect has a larger tensile stress relaxation effect than the transistor 40.

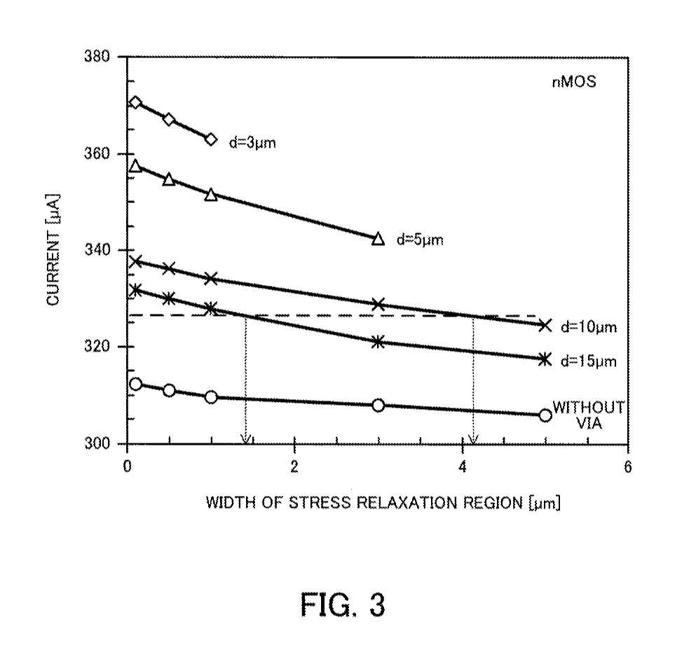

FIG. 3 illustrates examples of a relationship between the width of a stress relaxation region and a current that flows through an nMOS according to the first embodiment.

More specifically, FIG. 3 illustrates examples of simulation results, indicating a relationship between the width of a stress relaxation region (corresponding to the width W1 or W2 of the stress relaxation region 51 or 52) and a current when a distance d between an nMOS (corresponding to the transistor 30 or 40) formed in a semiconductor substrate (corresponding to the semiconductor substrate 10) and a via (corresponding to the via 20) is changed. FIG. 3 also illustrates an example of a simulation result obtained from a semiconductor substrate without a via. The distance d is defined by the distance between an end of the via and the center of the channel region of the nMOS. Herein, the distance d is changed to 3 μm, 5 μm, 10 μm, and 15 μm. The nMOS is a 65-nm process transistor, and the gate voltage Vg and the drain voltage Vd are 1.2 V.

As seen from FIG. 3, regardless of the distance d from the via, the current flowing through the nMOS tends to decrease as the width of the stress relaxation region increases. This tendency becomes more significant as the distance d between the nMOS and the via is shortened. In addition, as indicated by a chain line in FIG. 3, it is seen that the same current flows through two nMOSs when the widths of the respective stress relaxation regions are appropriately set, even when the distance d from the via differs.

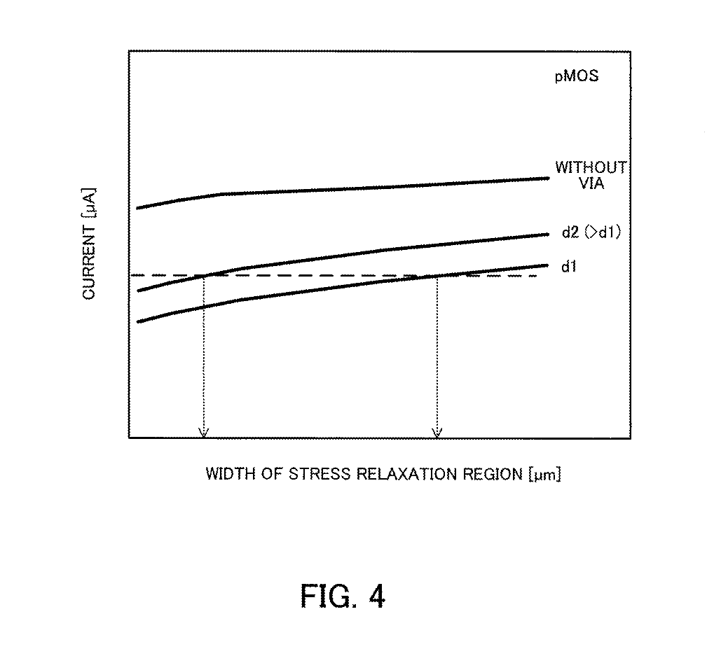

FIG. 4 illustrates examples of a relationship between the width of a stress relaxation region and a current that flows through a pMOS according to the first embodiment.

More specifically, FIG. 4 illustrates examples of a relationship between the width of a stress relaxation region (corresponding to the width W1 or W2 of the stress relaxation region 51 or 52) and a current when the distance between a pMOS (corresponding to the transistor 30 or 40) formed in a semiconductor substrate (corresponding to the semiconductor substrate 10) and a via (corresponding to the via 20) is set to be d1 and d2 (>d1). FIG. 4 also illustrates an example of a relationship obtained from a semiconductor substrate without a via. Each of the distances d1 and d2 is defined by the distance between an end of the via and the center of the channel region of the pMOS.

As seen from FIG. 4, regardless of the distance (d1 or d2) from the via, the current flowing through the pMOS tends to increase as the width of the stress relaxation region increases. As is the case with the above nMOS, it is seen that, as indicated by a chain line in FIG. 4, the same current flows through two pMOSs when the widths of the respective stress relaxation regions are appropriately set, even when the distance between one pMOS and the via is the distance d1 and the distance between the other pMOS and the via is the distance d2.

On the basis of the knowledge acquired from FIGS. 3 and 4, the distance between the via 20 and the transistor 30, the distance between the via 20 and the transistor 40, and the widths W1 and W2 of the respective stress relaxation regions 51 and 52 are appropriately set when the semiconductor device 1 is manufactured.

Namely, the stress relaxation region 51 having the wider width W1 is formed for the transistor 30, which is closer to the via 20 and is more affected by the tensile stress generated by the formation of the via 20, between the via 20 and the transistor 30. With the relatively large compressive stress increase effect by the stress relaxation region 51 having the wider width W1, a relatively large relaxation effect is obtained to control the tensile stress generated by the formation of the via 20 in the transistor 30.

In contrast, the stress relaxation region 52 having the narrower width W2 is formed for the transistor 40, which is farther from the via 20 and is less affected by the tensile stress generated by the formation of the via 20, between the transistors 30 and 40. With the relatively small compressive stress increase effect by the stress relaxation region 52 having the narrower width W2, a relatively small relaxation effect is obtained to control the tensile stress generated by the formation of the via 20 in the transistor 40.

By appropriately setting the distance between the via 20 and the transistor 30, the distance between the via 20 and the transistor 40, and the widths W1 and W2 of the stress relaxation regions 51 and 52 when the semiconductor device 1 is manufactured, the compressive stress increase effect and the tensile stress relaxation effect are adjusted. As a result, whether the transistors 30 and 40 are formed as nMOSs or pMOSs, the characteristics of the transistors 30 and 40 (the currents flowing therethrough) are made more uniform.

The transistors 30 and 40 of the semiconductor device 1 do not need to be formed sufficiently away from the via 20 in order to control the difference between the characteristics of the transistors 30 and 40. By adjusting each of the widths W1 and W2 of the stress relaxation regions 51 and 52, even when transistors 30 and 40 are formed close to the via 20, the transistors 30 and 40 have more uniform characteristics. Thus, improvement is made on the above decrease of the effective element area, namely, about the area penalty problem.

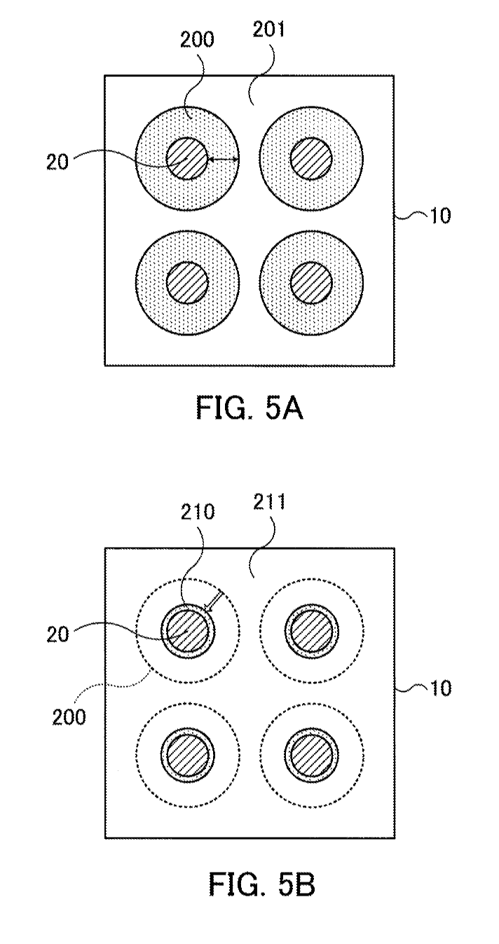

FIGS. 5A and 5B illustrate area penalties.

More specifically, each of FIGS. 5A and 5B is a schematic plan view illustrating a main portion of a semiconductor substrate 10 including vias 20 (four vias 20 in FIGS. 5A and 5B as an example). FIG. 5A illustrates area penalties 200 when the configuration illustrated in FIG. 2A without any stress relaxation region (neither the stress relaxation region 51 nor 52) is adopted. In FIG. 5A, the outer side of the area penalties 200 is an effective element area 201. In addition, FIG. 5B illustrates area penalties 210 when the configuration illustrated in FIG. 1 with stress relaxation regions (the above stress relaxation regions 51 and 52) is adopted. In FIG. 5B, the outer side of the area penalties 210 is an effective element area 211.

When the semiconductor substrate 10 in FIG. 5B is manufactured, an individual stress relaxation region having a predetermined width is formed, and a group of transistors are formed near an individual via 20. In this way, as illustrated in FIG. 5B, the individual area penalty 210 has a smaller size than that of the individual area penalty 200 (indicated by a dotted line in FIG. 5B) illustrated in FIG. 5A. For example, a case when the area penalties 200 of 20 μm are replaced by the area penalties 210 of 10 μm will be examined. If an individual via 20 has a diameter of 10 μm and these vias 20 are formed at intervals of 75 μm, the effective element area 211 is larger than the effective element area 201 by approximately 30%.

For example, the stress relaxation regions 51 and 52 having the widths W1 and W2, respectively, may be formed in the semiconductor substrate 10 of the semiconductor device 1 with the same depth.

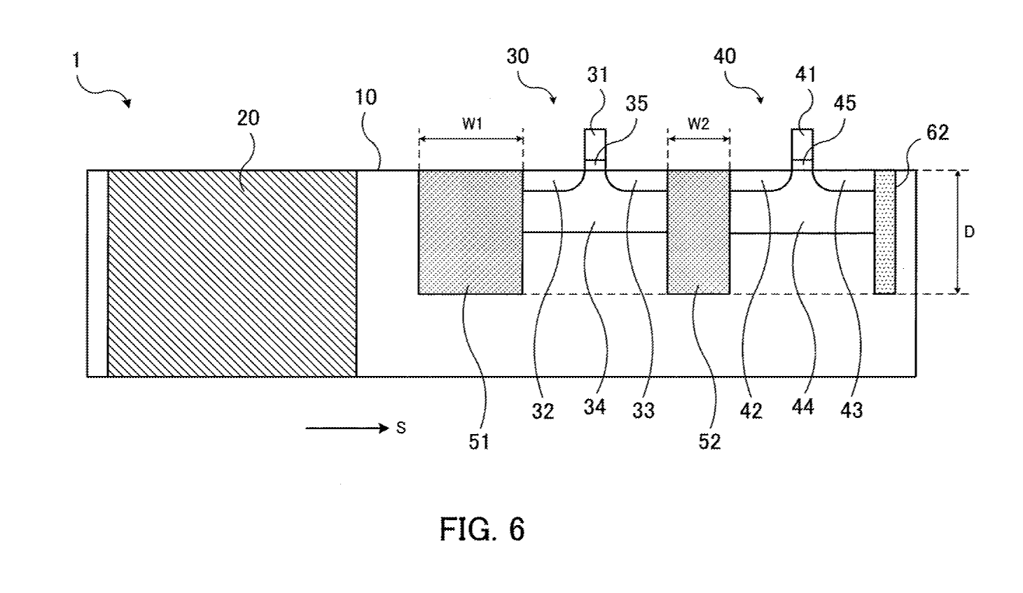

FIG. 6 illustrates a first example of the semiconductor device 1 according to the first embodiment. More specifically, FIG. 6 is a schematic cross section illustrating a main portion of a first example of the semiconductor device 1 according to the first embodiment, the schematic cross section being taken along line L1-L1 in FIG. 1.

The semiconductor device 1 illustrated as an example in FIG. 6 includes the stress relaxation region 51 having the width W1 and a depth D formed in the semiconductor substrate 10 and the stress relaxation region 52 having the narrower width W2 and the depth D. The stress relaxation region 51 having the width W1 and the depth D is formed between the via 20 formed in the semiconductor substrate 10 and the transistor 30 away from the via 20 by a predetermined distance. The stress relaxation region 52 having the narrower width W2 and the depth D is formed between the transistor 30 and the transistor 40 farther from the via 20.

The transistor 30 is formed in a predetermined conductive type well region 34 formed in an active region in the element isolation region including the stress relaxation regions 51 and 52 of the semiconductor substrate 10. The gate electrode 31 is formed on the semiconductor substrate 10 above the well region 34 via a gate insulating film 35, and the source region 32 and the drain region 33 are formed in the semiconductor substrate 10 on both sides of the gate electrode 31.

Likewise, the transistor 40 is formed in a predetermined conductive type well region 44 formed in an active region in the element isolation region including the stress relaxation region 52 of the semiconductor substrate 10. The gate electrode 41 is formed on the semiconductor substrate 10 above the well region 44 via a gate insulating film 45, and the source region 42 and the drain region 43 are formed in the semiconductor substrate 10 on both sides of the gate electrode 41.

As illustrated in FIG. 6, the stress relaxation regions 51 and 52 may be formed to have the same depth D. For example, the depth of the element isolation region including the stress relaxation regions 51 and 52 in the semiconductor substrate 10 may be set to be constant. Even when the stress relaxation regions 51 and 52 have the same depth D, the compressive stress increase effect and the tensile stress relaxation effect are adjusted by appropriately setting the widths W1 and W2. Namely, the characteristics of the transistors 30 and 40 are made more uniform.

The stress relaxation regions 51 and 52 may be formed to have different depths.

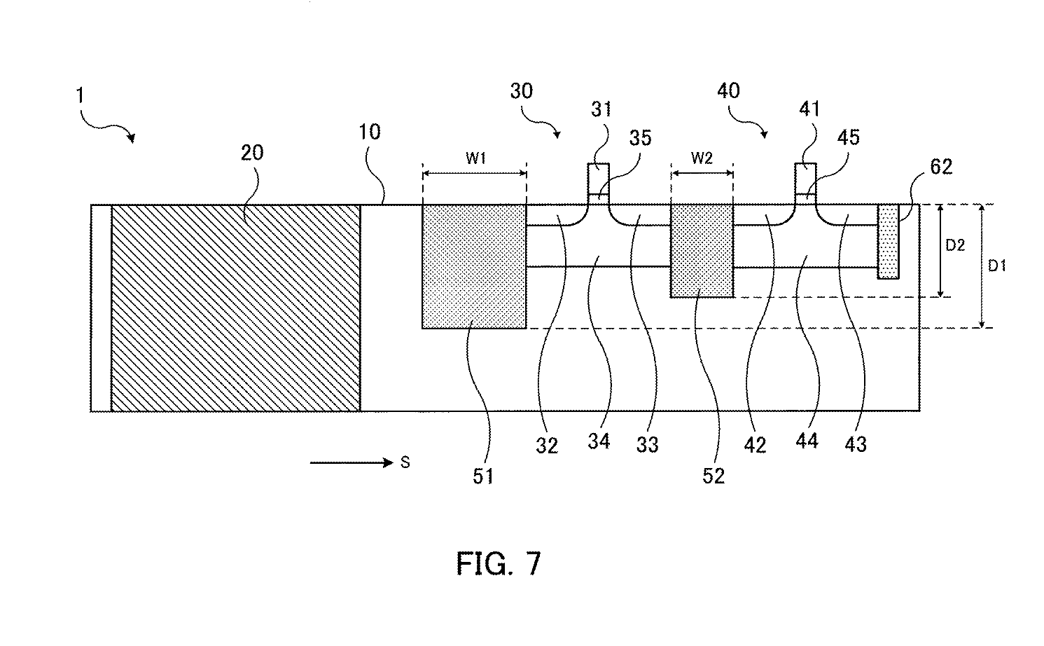

FIG. 7 illustrates a second example of the semiconductor device 1 according to the first embodiment. More specifically, FIG. 7 is a schematic cross section illustrating a main portion of a second example of the semiconductor device 1 according to the first embodiment, the schematic cross section being taken along line L1-L1 in FIG. 1.

For example, as illustrated in FIG. 7, the stress relaxation region 51 having the width W1 may be formed to have a depth D1, and the stress relaxation region 52 having the width W2 may be formed to have a depth D2 shallower than the depth D1 of the stress relaxation region 51. For example, the depth of the element isolation region including the stress relaxation regions 51 and 52 in the semiconductor substrate 10 is set such that a part farther from the via 20 has a shallower depth. The other aspects of the configuration are the same as those illustrated in FIG. 6.

In this way, by forming the stress relaxation region 51 having the width W1 and the depth D1 and the stress relaxation region 52 having the narrower width W2 and the shallower depth D2, the compressive stress increase effect and the tensile stress relaxation effect are adjusted. Namely, the characteristics of the transistors 30 and 40 are made more uniform.

While the above description has been made on the basis of an example in which the stress relaxation regions 51 and 52 are formed to have the different widths W1 and W2 of the stress relaxation region, the equivalent advantageous effect is obtained by forming the stress relaxation regions 51 and 52 having the same width as the widths W1 and W2 and different depths.

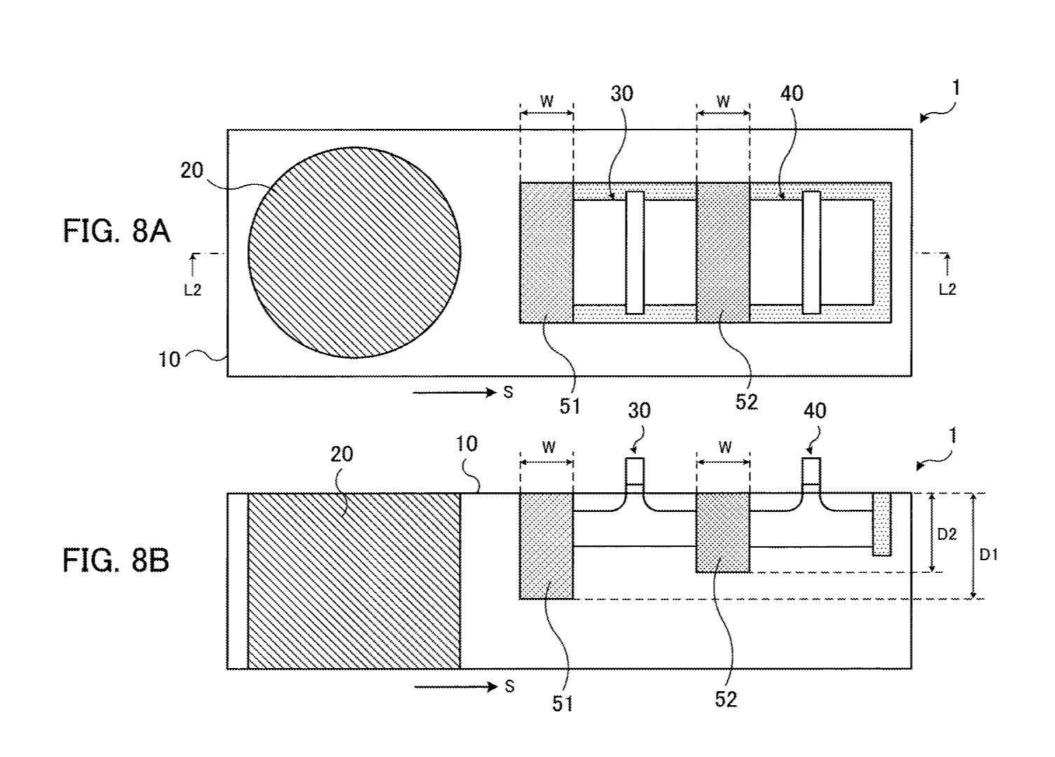

FIGS. 8A and 8B illustrate a third example of the semiconductor device 1 according to the first embodiment. More specifically, FIG. 8A is a schematic plan view illustrating a main portion of a third example of the semiconductor device 1 according to the first embodiment.

In addition, FIG. 8B is a schematic cross section illustrating the main portion of the third example of the semiconductor device 1 according to the first embodiment, the schematic cross section being taken along line L2-L2 in FIG. 8A.

For example, as illustrated in FIGS. 8A and 8B, the stress relaxation region 51 having the width W and the depth D1 is formed between the via 20 formed in the semiconductor substrate 10 and the transistor 30 formed away from the via 20 by a predetermined distance. The stress relaxation region 52 having the same width W and the shallower depth D2 between the transistor 30 and the transistor 40 farther from the via 20. The other aspects of the configuration are the same as those in FIGS. 6 and 7.

In this way, by forming the stress relaxation regions 51 and 52 having the same width W and the respective depths D1 and D2, the compressive stress increase effect and the tensile stress relaxation effect may be adjusted. Namely, the characteristics of the transistors 30 and 40 are made more uniform.

With the above configurations and methods according to the first embodiment, the high-performance semiconductor device 1 including the transistors 30 and 40 having more uniform characteristics is obtained. In addition, since the semiconductor substrate 10 has a larger effective element area, improvement is made on the integration (density) or downsizing of the semiconductor device 1.

Next, a second embodiment will be described.

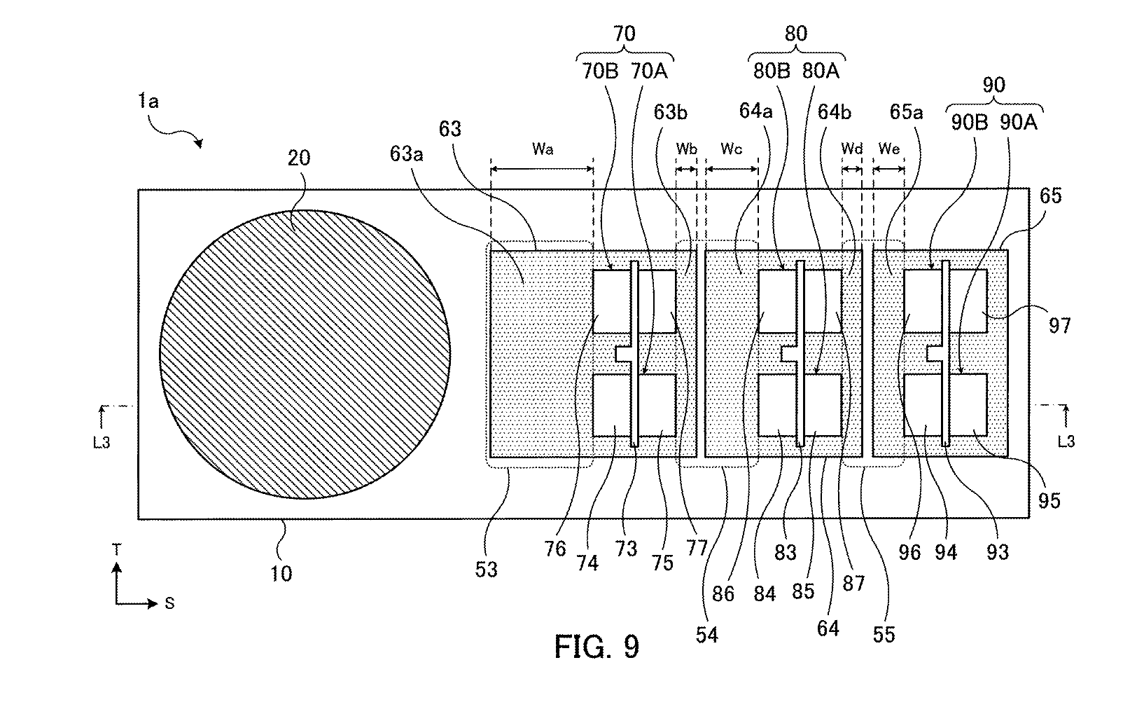

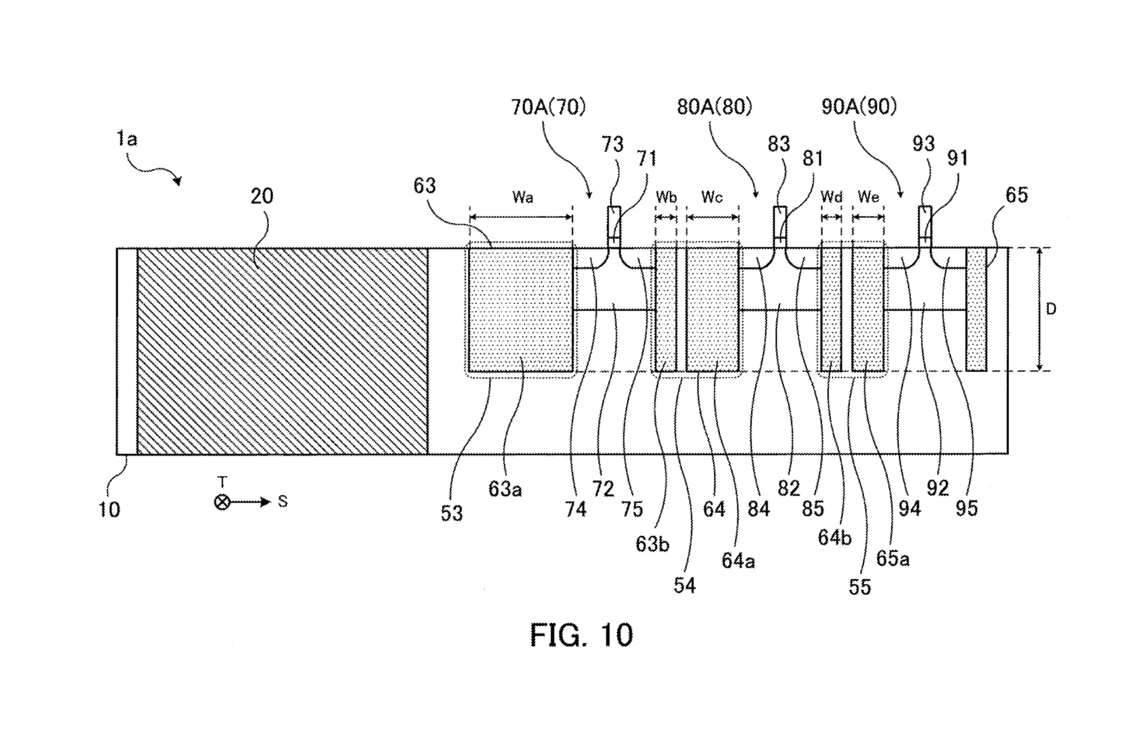

FIGS. 9 and 10 illustrate an example of a semiconductor device 1a according to a second embodiment. More specifically, FIG. 9 is a schematic plan view illustrating a main portion of an example of the semiconductor device 1a according to the second embodiment. In addition, FIG. 10 is a schematic cross section illustrating the main portion of the example of the semiconductor device 1a according to the second embodiment, the schematic cross section being taken along line L3-L3 in FIG. 9.

The semiconductor device 1a illustrated in FIGS. 9 and 10 includes a semiconductor substrate 10, a via 20, and a group of complementary MOSs (CMOSs) (in FIGS. 9 and 10, three CMOSs 70, 80, and 90 as an example). The CMOSs 70 to 90 are formed side by side in a lateral direction S of the via 20.

The CMOS 70 includes an nMOS 70A and a pMOS 70B. The nMOS 70A and the pMOS 70B are formed side by side in a direction T perpendicular to the direction S in the planar view. The nMOS 70A is formed in a p-type well region 71 (FIG. 10) formed in the semiconductor substrate 10. The nMOS 70A includes a gate electrode 73 formed on the semiconductor substrate 10 via a gate insulating film 72 (FIG. 10) and an n-type source region 74 and drain region 75 formed in the semiconductor substrate 10 on both sides of the gate electrode 73. The pMOS 70B is formed in an n-type well region (not illustrated) formed in the semiconductor substrate 10. The pMOS 70B includes the gate electrode 73 formed on the semiconductor substrate 10 via a gate insulating film (not illustrated) and a p-type source region 76 and drain region 77 formed in the semiconductor substrate 10 on both sides of the gate electrode 73. The nMOS 70A and pMOS 70B share the gate electrode 73.

The CMOS 80 includes an nMOS 80A and a pMOS 80B. The nMOS 80A and the pMOS 80B are formed side by side in the direction T perpendicular to the direction S in the planar view. The nMOS 80A is formed in a p-type well region 81 (FIG. 10) formed in the semiconductor substrate 10. The nMOS 80A includes a gate electrode 83 formed on the semiconductor substrate 10 via a gate insulating film 82 (FIG. 10) and an n-type source region 84 and drain region 85 formed in the semiconductor substrate 10 on both sides of the gate electrode 83. The pMOS 80B is formed in an n-type well region (not illustrated) formed in the semiconductor substrate 10. The pMOS 80B includes the gate electrode 83 shared with the nMOS 80A and formed on the semiconductor substrate 10 via a gate insulating film (not illustrated) and a p-type source region 86 and drain region 87 formed in the semiconductor substrate 10 on both sides of the gate electrode 83.

The CMOS 90 includes an nMOS 90A and a pMOS 90B. The nMOS 90A and the pMOS 90B are formed side by side in the direction T perpendicular to the direction S in the planar view. The nMOS 90A is formed in a p-type well region 91 (FIG. 10) formed in the semiconductor substrate 10. The nMOS 90A includes a gate electrode 93 formed on the semiconductor substrate 10 via a gate insulating film 92 (FIG. 10) and an n-type source region 94 and drain region 95 formed in the semiconductor substrate 10 on both sides of the gate electrode 93. The pMOS 90B is formed in an n-type well region (not illustrated) formed in the semiconductor substrate 10. The pMOS 90B includes the gate electrode 93 shared with the nMOS 90A and formed on the semiconductor substrate 10 via a gate insulating film (not illustrated) and a p-type source region 96 and drain region 97 formed in the semiconductor substrate 10 on both sides of the gate electrode 93.

The nMOS 70A and pMOS 70B of the CMOS 70, the nMOS 80A and pMOS 80B of the CMOS 80, and the nMOS 90A and pMOS 90B of the CMOS 90 have their respective channel directions (gate length directions) that match the direction S.

When a silicon substrate is used as the semiconductor substrate 10, the crystal face of the silicon substrate in the channel direction is formed on the (001) or (110) face. For example, in the case of a pMOS, the (110) face, from which a relatively high carrier mobility is obtained, is used.

The CMOS 70 is formed in a region demarcated by an element isolation region 63 formed in the semiconductor substrate 10 by using an STI method or the like. A part 63a of the element isolation region 63 between the via 20 and the CMOS 70 functions as a stress relaxation region 53.

The CMOS 80 is formed in a region demarcated by an element isolation region 64 formed in the semiconductor substrate 10 by using an STI method or the like. A part 63b of the element isolation region 63 and a part 64a of the element isolation region 64, the parts 63b and 64a being located between the CMOSs 70 and 80, function as a stress relaxation region 54.

The CMOS 90 is formed in a region demarcated by an element isolation region 65 formed in the semiconductor substrate 10 by using an STI method or the like. A part 64b of the element isolation region 64 and a part 65a of the element isolation region 65, the parts 64b and 65a being located between the CMOSs 80 and 90, function as a stress relaxation region 55.

Insulating material such as SiO is used for the element isolation regions 63 to 65.

The element isolation regions 63 to 65 are formed separately from each other in FIGS. 9 and 10. However, alternatively, these regions 63 to 65 may be formed continuously (as an integrated element isolation region).

The stress relaxation region 53 between the via 20 and the CMOS 70 is formed to be wider than the stress relaxation region 54 between the CMOSs 70 and 80. The stress relaxation region 54 is formed to be wider than the stress relaxation region 55 between the CMOSs 80 and 90.

In the example in FIGS. 9 and 10, the part 63a, which functions as the stress relaxation region 53 and which is included in the element isolation region 63, has a width Wa. This width Wa is formed to be larger than the sum of a width Wb of the part 63b, which is included in the element isolation region 63, and a width Wc of the part 64a, which is included in the element isolation region 64, the parts 63b and 64a functioning as the stress relaxation region 54 (Wa>Wb+Wc). In addition, the sum of the widths Wb and Wc (Wb+Wc) is set to be larger than the sum of a width Wd of the part 64b, which is included in the element isolation region 64, and a width We of the part 65a, which is included in the element isolation region 65, the parts 64b and 65a functioning as the stress relaxation region 55 (Wb+We>Wd+We).

In the example in FIGS. 9 and 10, the stress relaxation regions 53 to 55 are formed to have the same depth D.

The semiconductor device 1a having the above configuration will be described in detail.

As described with reference to FIGS. 2A and 2B, when a stress relaxation region is not formed, the closer an nMOS is formed to a via, the larger the stress in the direction S generated by the formation of the via will be. Consequently, since the tensile stress that affects the channel region is increased, a larger current flows through the nMOS. In contrast, when a stress relaxation region is not formed, the closer a pMOS is formed to a via, the larger the stress generated by the formation of the via will be. Consequently, since the compressive stress of the element isolation region less affects the channel region, a smaller current flows through the pMOS. Thus, the closer a CMOS including an nMOS and a pMOS arranged side by side in the direction T perpendicular to the direction S is located to a via, the larger the difference between the currents flowing through the respective nMOS and pMOS will be.

However, with the above semiconductor device 1a, the relatively wider stress relaxation region 53 is formed between the via 20 and the CMOS 70 closest thereto. With the compressive stress increase effect consequently obtained, the tensile stress on the channel region of the nMOS 70A is reduced, and the current flowing through the nMOS 70A is reduced. In addition, the compressive stress on the channel region of the pMOS 70B is increased, and the current flowing through the pMOS 70B is increased. As a result, the difference between the currents flowing through the respective nMOS 70A and pMOS 70B is reduced.

The same applies to the CMOSs 80 and 90. Namely, the stress relaxation region 54 formed between the CMOSs 80 and 70 reduces the current flowing through the nMOS 80A and increases the current flowing through the pMOS 80B. As a result, the difference between the currents flowing through the respective nMOS 80A and pMOS 80B is reduced. Likewise, the stress relaxation region 55 formed between the CMOSs 90 and 80 reduces the current flowing through the nMOS 90A and increases the current flowing through the pMOS 90B. As a result, the difference between the currents flowing through the respective nMOS 90A and pMOS 90B is reduced.

As described in the above first embodiment, the sizes (the widths in the second embodiment) of the stress relaxation regions 53 to 55 are appropriately set. In this way, more uniform currents flow through the nMOSs 70A to 90A, which are formed side by side in the direction S of the via 20. Likewise, more uniform currents flow through the pMOSs 70B to 90B, which are formed side by side in the direction S of the via 20.

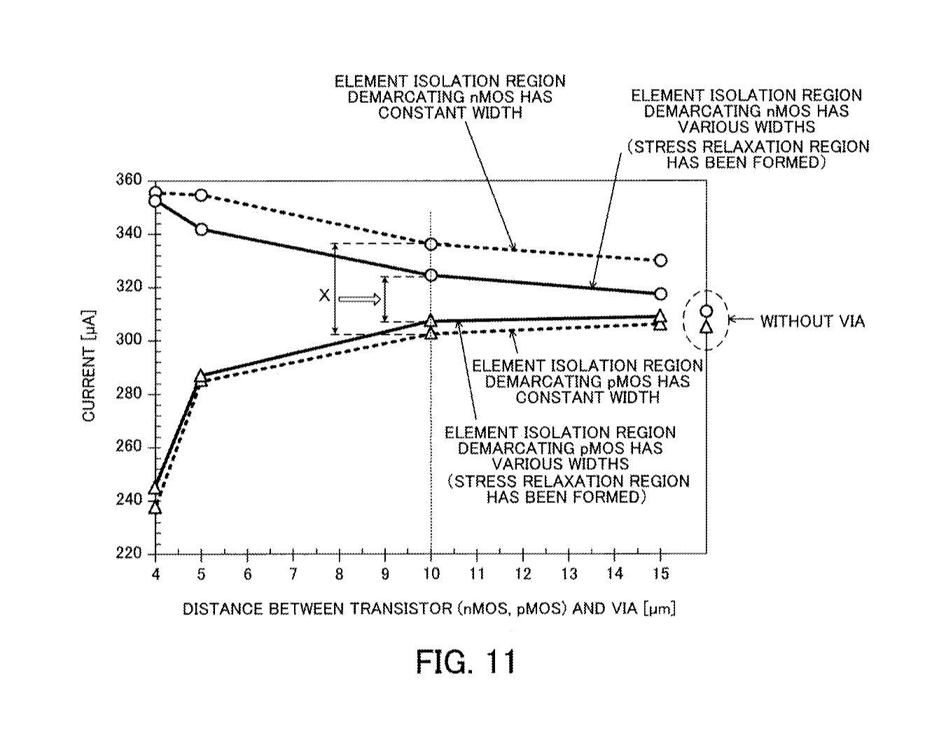

FIG. 11 illustrates an example of characteristics of transistors of the semiconductor device 1a according to the second embodiment.

More specifically, FIG. 11 illustrates examples of simulation results, indicating a relationship between the distance from an individual MOS (an nMOS and an pMOS) to a via formed in a semiconductor substrate and a current. The distance from the individual MOS (an nMOS and a pMOS) to the via is defined by the distance between an end of the via and the center of the channel region of the individual MOS (an nMOS and a pMOS). In FIG. 11, an individual dotted line indicates a relationship between the distance between a MOS (an nMOS or a pMOS) demarcated by an element isolation region having a certain width of 0.5 μm and the via and a current flowing through the MOS. In FIG. 11, an individual line indicates a relationship between the distance between a MOS (nMOS and pMOS) demarcated by an element isolation region whose width (the width of the stress relaxation region) has been optimized in the range between 0.1 μm and 5 μm and the via and a current flowing through the MOS. For comparison, FIG. 11 also illustrates currents flowing through the respective nMOS and pMOS when no via is formed. The nMOS and pMOS are 65-nm process transistors. The nMOS has a gate voltage Vg and drain voltage Vd of 1.2 V, and the pMOS has a gate voltage Vg and drain voltage Vd of −1.2 V.

As illustrated in FIG. 11, when the nMOS demarcated by the element isolation region having the constant width is located farther from the via, a smaller current tends to flow through the nMOS. In the case of the nMOS (corresponding to the above nMOSs 70A to 90A) formed next to a stress relaxation region having a predetermined width between the nMOS and the via, the stress relaxation region having been formed by changing the width of the element isolation region on the basis of the distance from the via, a smaller current flows, compared with the nMOS demarcated by the element isolation region having the constant width.

In contrast, as illustrated in FIG. 11, when the pMOS demarcated by the element isolation region having the constant width is located farther from the via, a larger current tends to flow through the pMOS. In the case of the pMOS (corresponding to the above pMOSs 70B to 90B) formed next to a stress relaxation region having a predetermined width between the pMOS and the via, the stress relaxation region having been formed by changing the width of the element isolation region on the basis of the distance from the via, a larger current flows, compared with the pMOS demarcated by the element isolation region having the constant width.

By forming a stress relaxation region, the difference between the currents flowing through the respective nMOS and pMOS is reduced. For example, when an nMOS and a pMOS are distanced from a via by 10 μm and when a stress relaxation region is formed, the difference X between the currents flowing through the respective nMOS and pMOS is reduced by about 51%, compared with a case in which the element isolation region has a certain width and no stress relaxation region is formed.

When a silicon substrate is used as the semiconductor substrate 10, the crystal face of the silicon substrate in the channel direction may be formed on the (110) face, from which a relatively high carrier mobility is obtained, for a pMOS. In this case, the current flowing through the pMOS is increased, and the difference from the current flowing through the nMOS is reduced.

In addition, when a distance of 10 μm from the via is set as the area penalty in which an nMOS and a pMOS of a CMOS fail to be formed around an individual via (an individual via has a diameter of 10 μm and the vias are formed at intervals of 75 μm), the effective element area is increased by about 30% (FIGS. 5A and 5B).

With the above semiconductor device 1a, by forming the stress relaxation regions 53 to 55, the difference among the currents flowing through the nMOS 70A and pMOS 70B of the CMOS 70, the nMOS 80A and pMOS 80B of the CMOS 80, and the nMOS 90A and pMOS 90B of the CMOS 90 is reduced. In addition, by forming the stress relaxation regions 53 to 55, the currents flowing through the respective nMOSs 70A, 80A and 90A are made more uniform, and the currents flowing through the respective pMOSs 70B, 80B, and 90B are made more uniform.

While the above description has been made by using an example in which the stress relaxation regions 53 to 55 have the constant depth D, each of the stress relaxation regions 53 to 55 may be formed to have a different depth.

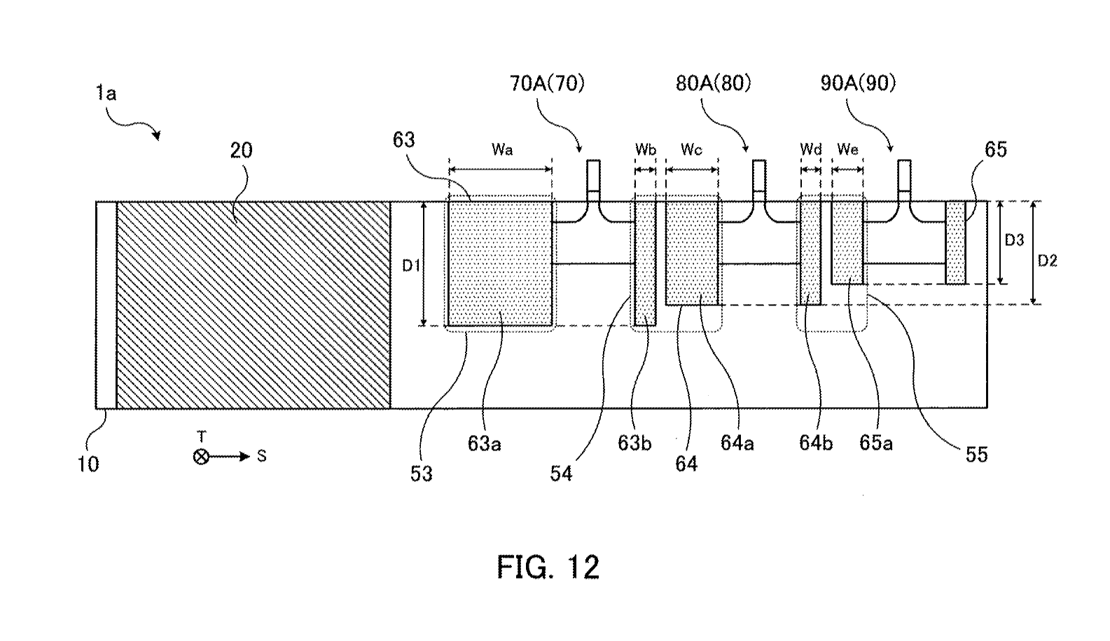

FIG. 12 illustrates another example of the semiconductor device 1a according to the second embodiment. More specifically, FIG. 12 is a schematic cross section illustrating a main portion of another example of the semiconductor device 1a according to the second embodiment.

For example, as illustrated in FIG. 12, the element isolation region 63 demarcating the CMOS 70 is formed to have a depth D1, the element isolation region 64 demarcating the CMOS 80 is formed to have a shallower depth D2, and the element isolation region 65 demarcating the CMOS 90 is formed to have an even shallower depth D3. In this way, the total size (volume) of the part 63b (width Wb) of the element isolation region 63 and the part 64a (width Wc) of the element isolation region 64, the parts 63b and 64a functioning as the stress relaxation region 54, is smaller than the size (volume) of the part 63a (width Wa) of the element isolation region 63, the part 63a functioning as the stress relaxation region 53. In addition, the total size (volume) of the part 64b (width Wd) of the element isolation region 64 and the part 65a (width We) of the element isolation region 65, the parts 64b and 65a functioning as the stress relaxation region 55, is smaller than the total size (volume) of the parts 63b and 64a.

With such configuration as illustrated in FIG. 12, by adjusting the compressive stress and tensile stress, the difference between the currents flowing through the nMOS and pMOS of each of the CMOSs 70 to 90 is reduced. Namely, the currents flowing through the nMOSs of the CMOSs 70 to 90 are made more uniform, and the currents flowing through the pMOSs of the CMOSs 70 to 90 are made more uniform.

Alternatively, the part 63b (width Wb) of the element isolation region 63 may be formed to have the depth D2, and the part 64b (width Wd) of the element isolation region 64 may be formed to have the depth D3. In this case, too, an equivalent advantageous effect is obtained.

With the above configurations and methods according to the second embodiment, the high-performance semiconductor device 1a including the CMOSs 70 to 90 having more uniform characteristics is obtained. In addition, since the semiconductor substrate 10 has a larger effective element area, improvement is made on the integration (density) or downsizing of the semiconductor device 1a.

Next, a third embodiment will be described.

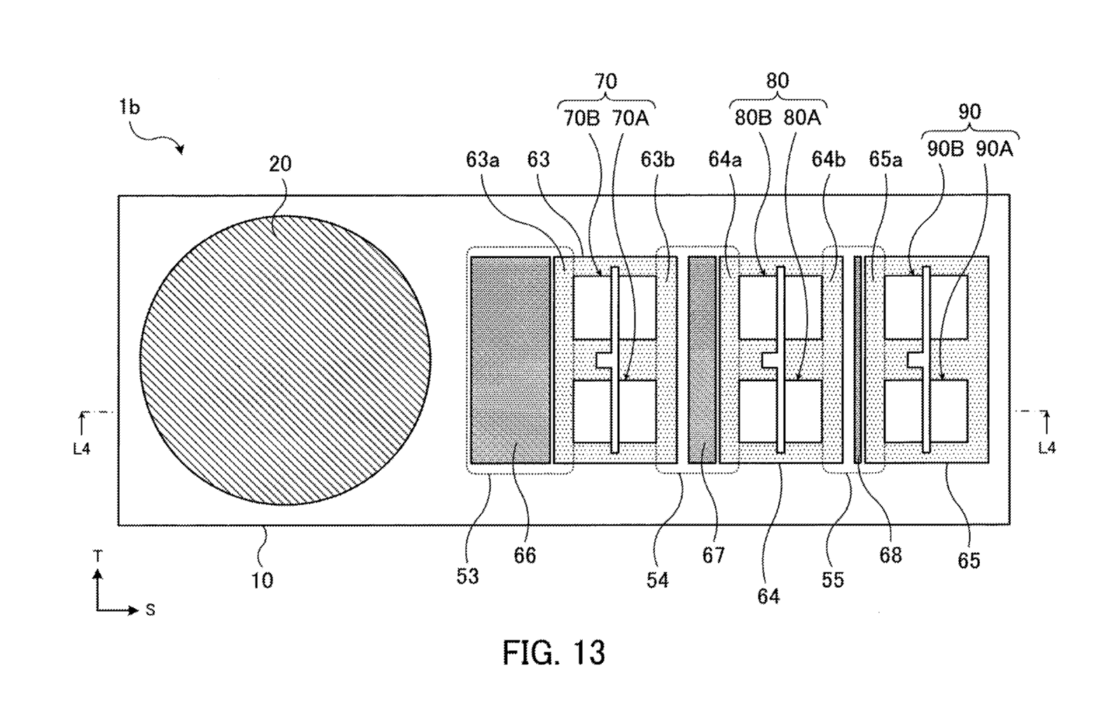

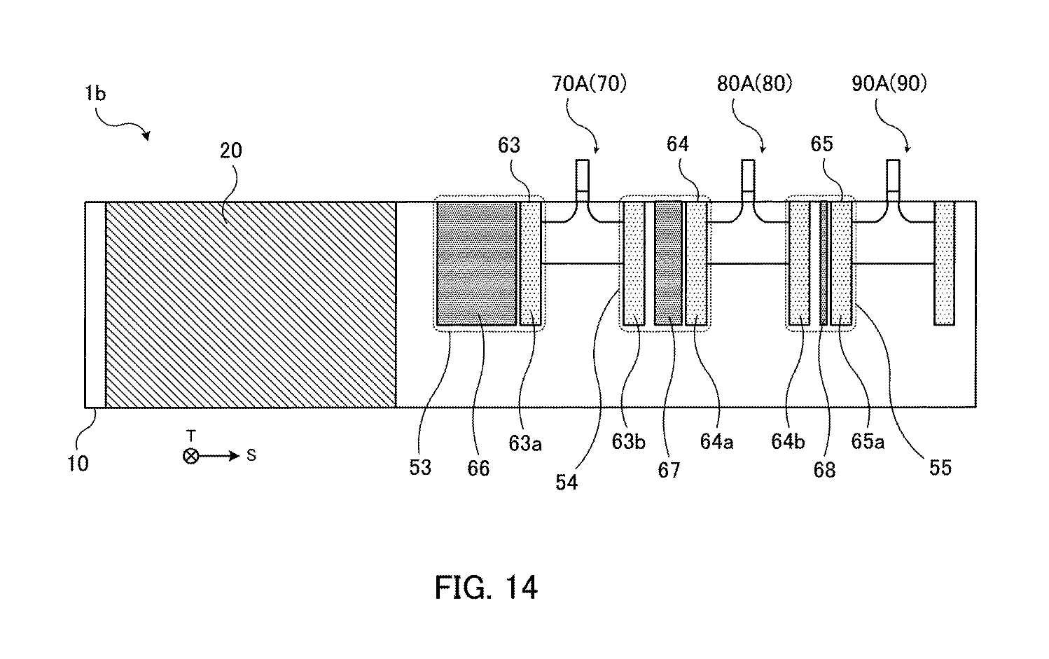

FIGS. 13 and 14 illustrate an example of a semiconductor device 1b according to a third embodiment. More specifically, FIG. 13 is a schematic plan view illustrating a main portion of an example of the semiconductor device 1b according to the third embodiment. In addition, FIG. 14 is a schematic cross section illustrating the main portion of the example of the semiconductor device 1b according to the third embodiment, the schematic cross section being taken along line L4-L4 in FIG. 13.

The semiconductor device 1b illustrated in FIGS. 13 and 14 differs from the semiconductor device 1a according to the second embodiment in that an individual stress relaxation region includes a part of an element isolation region and an insulating region for which predetermined insulating material is used.

Namely, in the semiconductor device 1b illustrated in FIGS. 13 and 14, a part 63a of an element isolation region 63 demarcating a CMOS 70 and an insulating region 66 formed between the part 63a and a via 20 function as a stress relaxation region 53.

A part 63b of the element isolation region 63 demarcating the CMOS 70, a part 64a of an element isolation region 64 demarcating a CMOS 80, and an insulating region 67 formed between the parts 63b and 64a function as a stress relaxation region 54.

A part 64b of the element isolation region 64 demarcating the CMOS 80, a part 65a of an element isolation region 65 demarcating a CMOS 90, and an insulating region 68 formed between the parts 64b and 65a function as a stress relaxation region 55.

The stress relaxation region 53 is formed to be wider than the stress relaxation region 54, and the stress relaxation region 54 is formed to be wider than the stress relaxation region 55. Namely, the sum of the width of the part 63a of the element isolation region 63 and the width of the insulating region 66 is set to be larger than the sum of the width of the part 63b of the element isolation region 63, the width of the part 64a of the element isolation region 64, and the width of the insulating region 67. In addition, the sum of the width of the part 63b of the element isolation region 63, the width of the part 64a of the element isolation region 64, and the width of the insulating region 67 is set to be larger than the sum of the width of the part 64b of the element isolation region 64, the width of the part 65a of the element isolation region 65, and the width of the insulating region 68.

The insulating regions 66 to 68 and the element isolation regions 63 to 65 are formed separately from each other in FIGS. 13 and 14. However, alternatively, these regions 63 to 68 may be formed continuously.

Each of the element isolation regions 63 to 65 may be formed to have a different depth. For example, as illustrated in FIG. 14, the insulating regions 66 to 68 are formed to have the same depth as that of the element isolation regions 63 to 65. The insulating regions 66 to 68 may be formed to have a depth different from that of the element isolation regions 63 to 65. Each of the insulating regions 66 to 68 may be formed to have a different depth from each other.

The insulating regions 66 to 68 are formed in a semiconductor substrate 10 by using an STI method, for example. For example, the insulating regions 66 to 68 may be formed simultaneously with the element isolation regions 63 to 65. Alternatively, after the element isolation regions 63 to 65 are formed, the insulating regions 66 to 68 may be formed. Alternatively, after the insulating regions 66 to 68 are formed, the element isolation regions 63 to 65 may be formed.

Insulating material such as SiO is used for the element isolation regions 63 to 65. For the insulating regions 66 to 68, insulating material such as a compound of Si with one or more elements such as O, N, or C is used. Namely, for the insulating regions 66 to 68, SiO, SiN, SiOC, SiCN, or the like is used.

In the semiconductor device 1b having the above configuration, as is the case with the semiconductor device 1a according to the second embodiment, the stress relaxation region 53 including the part 63a of the element isolation region 63 and the insulating region 66 reduces the difference between the currents flowing through an nMOS 70A and a pMOS 70B of the CMOS 70, respectively. In addition, the stress relaxation region 54 including the part 63b of the element isolation region 63, the part 64a of the element isolation region 64, and the insulating region 67 reduces the difference between the currents flowing through an nMOS 80A and a pMOS 80B of the CMOS 80, respectively. In addition, the stress relaxation region 55 includes the part 64b of the element isolation region 64, the part 65a of the element isolation region 65, and the insulating region 68 reduces the difference between the currents flowing through an nMOS 90A and a pMOS 90B of the CMOS 90, respectively.

In addition, with these stress relaxation regions 53 to 55, the currents flowing through the nMOSs 70A to 90A are made more uniform, and the currents flowing through the pMOSs 70B to 90B are made more uniform.

In addition, in the semiconductor device 1b, different material may be used for the element isolation region 63 (the part 63a) and the insulating region 66 included in the stress relaxation region 53. In addition, different material may be used for the element isolation regions 63 and 64 (the parts 63b and 64a) and the insulating region 67 included in the stress relaxation region 54. In addition, different material may be used for the element isolation regions 64 and 65 (the parts 64b and 65a) and the insulating region 68 included in the stress relaxation region 55.

Thus, depending on the material selected for the insulating regions 66 to 68, a compressive stress increase effect and a tensile stress relaxation effect different from those obtained when a single kind of material (for example, SiO) is used for the stress relaxation regions 53 to 55 are obtained. In this way, by appropriately adjusting the compressive stress and tensile stress, the difference between the currents flowing through the respective nMOS and pMOS of each of the CMOSs 70 to 90 is further reduced. Namely, the currents flowing through the nMOSs of the CMOSs 70 to 90 are made even more uniform, and the currents flowing through the pMOSs of the CMOSs 70 to 90 are made even more uniform.

With the above configurations and methods according to the third embodiment, the high-performance semiconductor device 1b including the CMOSs 70 to 90 having more uniform characteristics is obtained. In addition, since the semiconductor substrate 10 has a larger effective element area, improvement is made on the integration (density) or downsizing of the semiconductor device 1b.

Next, a fourth embodiment will be described.

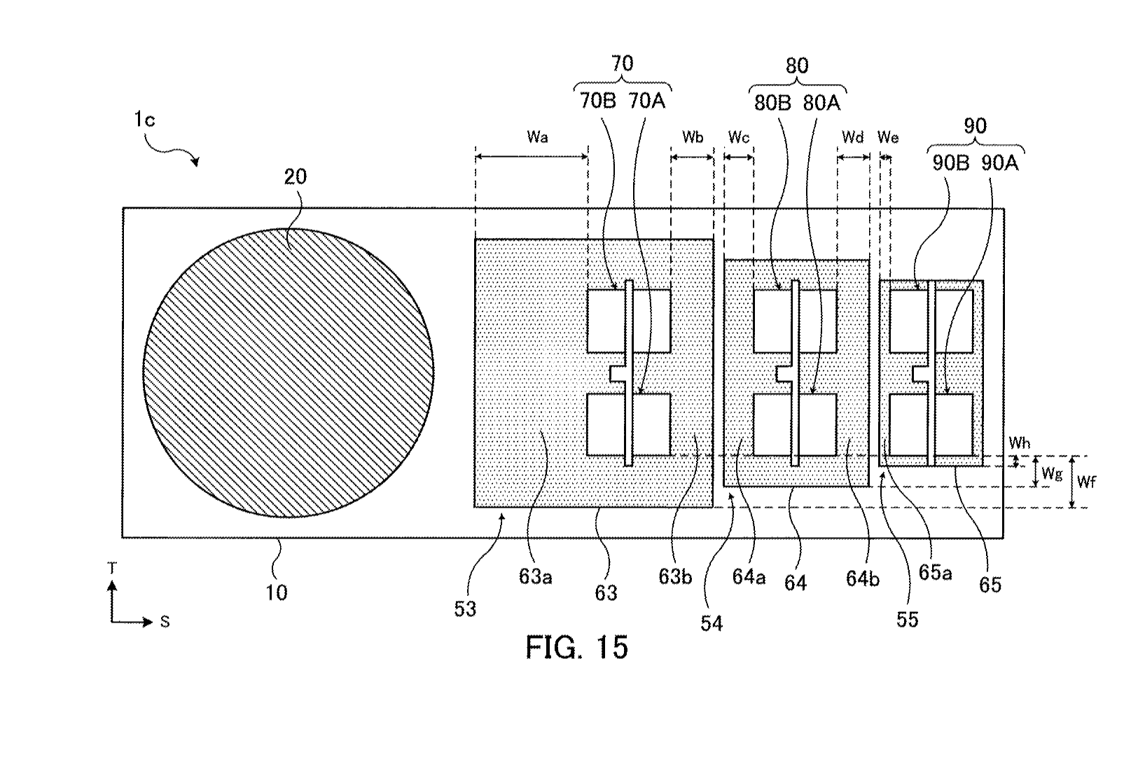

FIG. 15 illustrates an example of a semiconductor device 1c according to a fourth embodiment. More specifically, FIG. 15 is a schematic plan view illustrating a main portion of an example of the semiconductor device 1c according to the fourth embodiment.

The semiconductor device 1c illustrated in FIG. 15 differs from the semiconductor device 1a according to the second embodiment in that the widths of element isolation regions 63 to 65 in a direction T have been adjusted. The other aspects (and changes) of the configuration of the semiconductor device 1c may be the same as those of the semiconductor device 1a.

For example, the element isolation region 63 demarcating a CMOS 70 has a part having a width Wf in the direction T. The element isolation region 64 demarcating a CMOS 80 has a part having a width Wg in the direction T narrower than the width Wf. The element isolation region 65 demarcating a CMOS 90 has a part having a width Wh in the direction T even narrower than the width Wg (Wf>Wg>Wh).

In a direction S, as described above, a width Wa of a part 63a of the element isolation region 63 closest to a via 20 is formed to be wider than the sum of a width Wb of a part 63b of the element isolation region 63 and a width Wc of a part 64a of the element isolation region 64 (Wa>Wb+Wc). In addition, the sum (Wb+Wc) is set to be larger than the sum of a width Wd of a part 64b of the element isolation region 64 and a width We of a part 65a of the element isolation region 65 (Wb+We>Wd+We).

In the semiconductor device 1c having the above configuration, for example, the width Wf of the part of the element isolation region 63 in the direction T affects the compressive stress generated in the channel region of an nMOS 70A and a pMOS 70B of the CMOS 70. Namely, when the width Wf is increased, the compressive stress generated in the channel region of the nMOS 70A and pMOS 70B is increased. When the width Wf is decreased, the compressive stress generated in the channel region of the nMOS 70A and pMOS 70B is decreased. By adjusting the width Wf of the part in the direction T in addition to the width Wa of the part 63a of the element isolation region 63 in the direction S, the difference between the currents flowing through the nMOS 70A and pMOS 70B is reduced. The same applies to the element isolation regions 64 and 65.

With the above configuration and method according to the fourth embodiment, the high-performance semiconductor device 1c including the CMOSs 70 to 90 having more uniform characteristics is obtained. In addition, since the semiconductor substrate 10 has a larger effective element area, improvement is made on the integration (density) or downsizing of the semiconductor device 1c.

The widths of the stress relaxation region 51 and 52 and the element isolation regions 61 and 62 according to the above first embodiment in the direction T perpendicular to the direction S may be set as described in the fourth embodiment. The widths of the element isolation regions 63 to 65 described in the above second embodiment and the widths of the stress relaxation regions 53 to 55 and the element isolation regions 63 to 65 described in the above third embodiment in the direction T may be set as described in the fourth embodiment.

Alternatively, any combination of the configurations and methods described in the above second to fourth embodiments is possible. Namely, any one of the stress relaxation regions 53 described in any one of the above second to fourth embodiments may be formed between the via 20 and the CMOS 70. Any one of the stress relaxation regions 54 described in the above second to fourth embodiments may be formed between the CMOSs 70 and 80. Any one of the stress relaxation regions 55 described in the above second to fourth embodiments may be formed between the CMOSs 80 and 90.

Next, a fifth embodiment will be described.

Hereinafter, an example of a method of setting the width of a stress relaxation region adjacent to a CMOS as described in the above second to fourth embodiments will be described as the fifth embodiment.

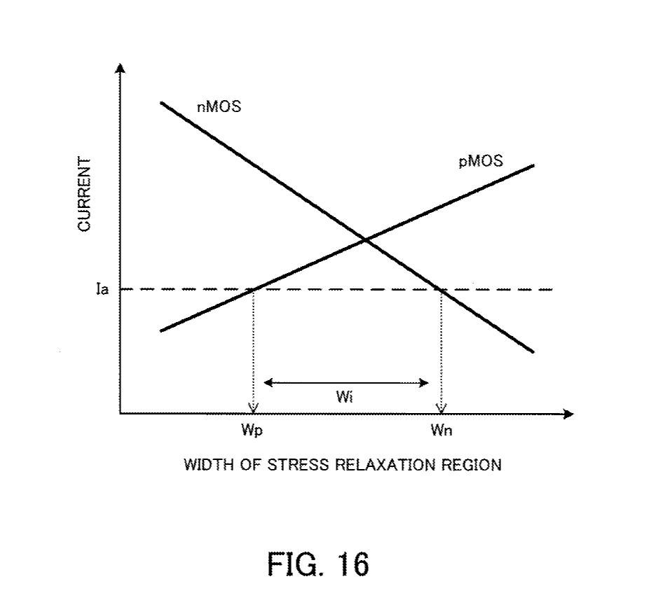

FIG. 16 illustrates an example of a method of setting the width of a stress relaxation region according to the fifth embodiment.

To set the width of a stress relaxation region between a CMOS including an nMOS and a pMOS and a via such as a TSV formed in a semiconductor substrate, for example, a relationship between the width of the stress relaxation region and currents flowing through the respective nMOS and pMOS as illustrated in FIG. 16 is acquired. As described in the above second to fourth embodiments, the CMOS is located in a lateral direction S of the via, and the nMOS and pMOS are formed side by side in a direction T perpendicular to the direction S. The direction S matches the channel directions of the nMOS and pMOS.

As illustrated in FIG. 16, the current flowing through the nMOS tends to decrease as the width of the stress relaxation region increases. In contrast, the current flowing through the pMOS tends to increase as the width of the stress relaxation region increases. From the relationship as illustrated in FIG. 16, first, a desired current value Ia, for example, a value of a current flowing through the nMOS and pMOS when the semiconductor substrate does not include a via, is set. Next, a width Wn of a stress relaxation region adjacent to the nMOS and a width Wp of a stress relaxation region adjacent to the pMOS when the set current value Ia flows through the nMOS and pMOS are extracted. Next, a width Wi of a stress relaxation region adjacent to the CMOS including the nMOS and pMOS is set in the range between the extracted width Wp of the stress relaxation region and the extracted width Wn of the stress relaxation region (Wp≦Wi≦Wn).

In this way, the width of a stress relaxation region between a via formed in a semiconductor substrate and a CMOS formed in the direction S of the via is set. In addition to the CMOS closest to the via, this setting method may also be used for setting the width of an stress relaxation region formed adjacent to an individual one of the CMOSs formed side by side in the direction S of the via.

Next, a sixth embodiment will be described.

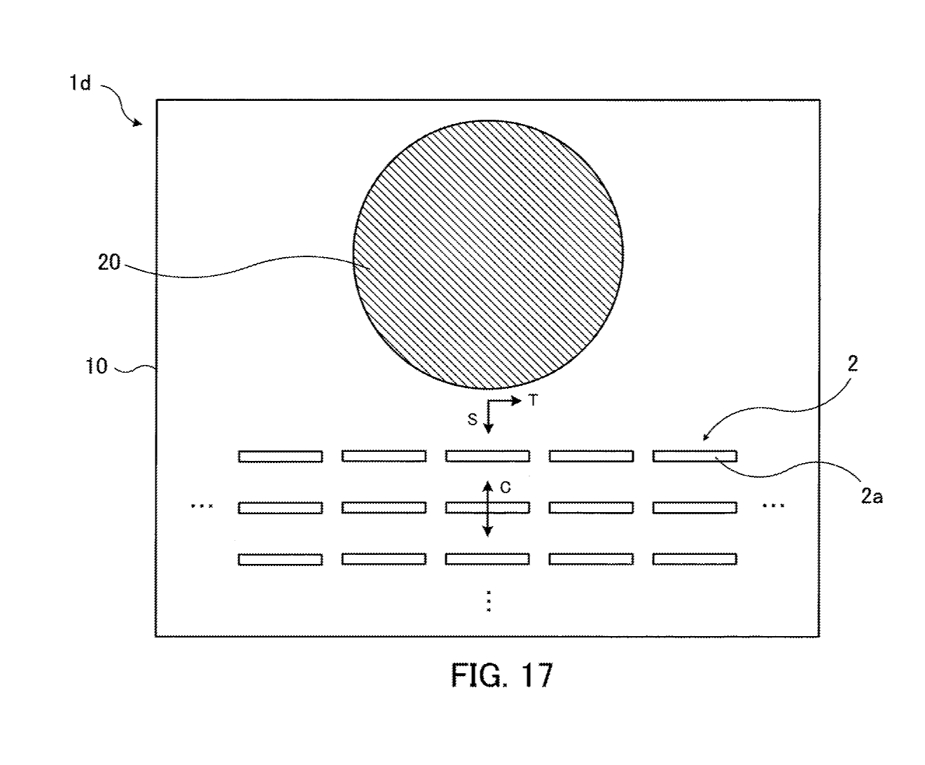

FIG. 17 illustrates an example of a semiconductor device 1d according to a sixth embodiment. FIG. 17 is a schematic plan view illustrating a main portion of an example of the semiconductor device 1d according to the sixth embodiment.

The configurations and methods according to the above first to fifth embodiments are applicable to the semiconductor device 1d configured as illustrated in FIG. 17. Namely, the configurations and methods are applicable to the semiconductor device 1d including a via 20 such as a TSV formed in a semiconductor substrate 10 and a group of transistors 2 that are formed side by side in a region in a lateral direction S of the via 20. The transistors 2 are formed in the direction S and a direction T perpendicular thereto. Each of the transistors 2 has a channel direction C that matches the direction S. For convenience, an individual transistor 2 is illustrated by its gate electrode 2a in FIG. 17. An individual transistor 2 is an nMOS or pMOS transistor or a CMOS transistor including nMOS and pMOS transistors.

By applying the configurations and methods according to the above first to fifth embodiments to the semiconductor device 1d configured as illustrated in FIG. 17, the characteristics of (the currents flowing through) the group of transistors 2 formed side by side in the direction S are made more uniform. When the transistors 2 are CMOSs, the difference between the currents flowing through the respective nMOS and pMOS of an individual CMOS is reduced. As a result, the high-performance semiconductor device 1d including the transistors 2 having more uniform characteristics is obtained. In addition, since the semiconductor substrate 10 has a larger effective element area, improvement is made on the integration (density) or downsizing of the semiconductor device 1d.

Next, a seventh embodiment will be described.

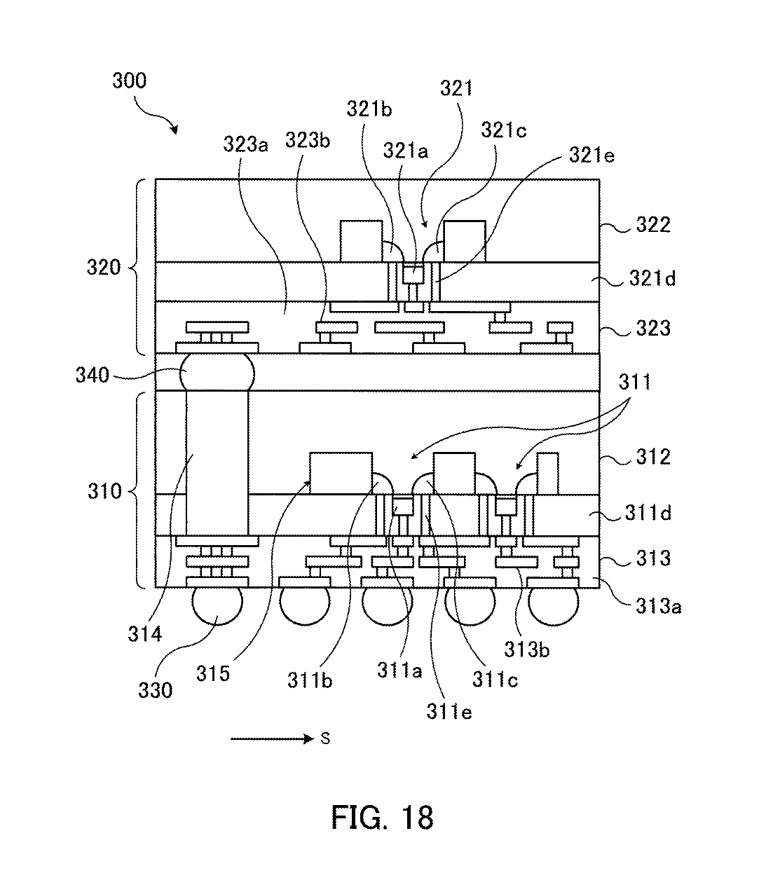

FIG. 18 illustrates an example of a semiconductor device 300 according to a seventh embodiment. FIG. 18 is a schematic cross section illustrating a main portion of an example of the semiconductor device 300 according to the seventh embodiment.

The semiconductor device 300 (which may also be referred to as an electronic apparatus) illustrated in FIG. 18 has a 3D configuration including a semiconductor device 310 and a semiconductor device 320 formed on top of the semiconductor device 310.

The lower semiconductor device 310 includes a semiconductor substrate 312 in which a group of transistors 311 (two transistors 311 in FIG. 18 as an example) are formed, wiring layers 313 that are formed on the semiconductor substrate 312, and a via 314 such as a TSV that runs through the semiconductor substrate 312 and that is connected to the wiring layers 313. Each of the transistors 311 includes a gate electrode 311a, a source region 311b, and a drain region 311c and has a channel direction (gate length direction) that matches a lateral direction S of the via 314. The wiring layers 313 include an insulating layer 313a and conducting layers 313b (wirings and vias) formed in the insulating layer 313a. The via 314 runs through the semiconductor substrate 312 and an insulating film 311d thereon and is connected to a predetermined part of the conducting layers 313b and to the gate electrode 311a, the source region 311b, and the drain region 311c of the transistor 311 via plugs 311e in the insulating film 311d. On the wiring layers 313, terminals 330 such as solder bumps are formed, so that the semiconductor device 310 is connected to another substrate such as a semiconductor device or a circuit board (not illustrated).

The upper semiconductor device 320 includes a semiconductor substrate 322 in which a transistor 321 (a single transistor in FIG. 18 as an example) is formed and wiring layers 323 formed on the semiconductor substrate 322. The wiring layers 323 include an insulating layer 323a and conducting layers 323b (wirings and vias) formed in the insulating layer 323a. A gate electrode 321a, a source region 321b, and a drain region 321c of the transistor 321 are connected to a predetermined part of the conducting layers 323b via plugs 321e in an insulating film 321d.

The via 314 of the lower semiconductor device 310 is connected to a predetermined part of the conducting layers 323b formed in the wiring layers 323 of the upper semiconductor device 320 via a terminal 340 such as a solder bump.

The upper semiconductor device 320 may include a via such as a TSV that runs through the semiconductor substrate 322 and that is connected to the wiring layers 323. In this case, by using the via, another semiconductor device may be mounted on the semiconductor device 320.

For example, an individual stress relaxation region 315 for relaxing the stress generated by the formation of the via 314 in the group of transistors 311 is formed in the lower semiconductor device 310 of the semiconductor device 300 having the above configuration.

As described in the examples described in the above first to fourth embodiments, the stress relaxation region 315 includes an element isolation region that demarcates the element region of the corresponding transistor 311 or a part of the element isolation region or includes a part of the element isolation region and an insulating region. The width of the stress relaxation region 315 formed between the via 314 and the transistor 311 closer to the via 314 is larger than that of the stress relaxation region 315 formed between the closer transistor 311 and the transistor 311 farther from the via 314. With these stress relaxation regions 315, the compressive stress increase effect and the tensile stress relaxation effect are adjusted. As a result, the characteristics of the group of transistors 311 are made more uniform. In addition, with these stress relaxation regions 315, the effective element area of the semiconductor substrate 312 is expanded.

Consequently, the high-performance semiconductor device 310 including the group of transistors 311 having more uniform characteristics is obtained. Next, by mounting the semiconductor device 320 on the semiconductor device 310, the high-performance semiconductor device 300 is obtained. In addition, since the effective element area is expanded, improvement is made on integration or downsizing of the semiconductor device 310. Therefore, improvement is also made on performance or downsizing of the semiconductor device 300.

Next, an eighth embodiment will be described.

Semiconductor devices to which at least one of the configurations and methods according to the above first to seventh embodiments has been applied may be mounted on various kinds of electronic apparatuses. For example, such semiconductor devices may be used for various kinds of electronic apparatus such as computers (personal computers, supercomputers, servers, etc.), smartphones, mobile phones, tablet terminals, sensors, cameras, audio apparatuses, measuring apparatuses, inspection apparatuses, and manufacturing apparatuses.

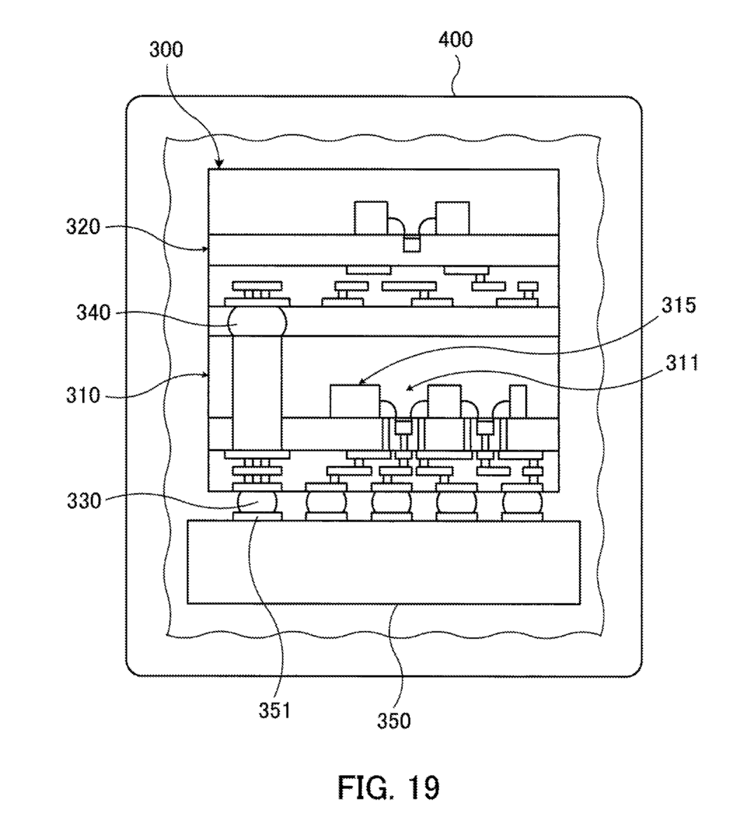

FIG. 19 schematically illustrates an example of an electronic apparatus 400 according to the eighth embodiment.

As illustrated in FIG. 19, for example, the semiconductor device 300 as illustrated in FIG. 18 is mounted on a circuit board 350 such as a mother board, and the resultant device is then mounted on (included in) the electronic apparatus 400. The circuit board 350 has terminals 351 such as pads at locations corresponding to the terminals 330 of the semiconductor device 310. By bonding the matching terminals 330 and terminals 351, the semiconductor device 310 (the semiconductor device 300 including the semiconductor device 310) is mounted on the circuit board 350.

By forming the stress relaxation regions 315 each having a predetermined width in the semiconductor device 300 as described above, the characteristics among the group of transistors 311 are made more uniform, and the effective element area of the semiconductor substrate 312 is expanded. As a result, improvement is made on the performance or downsizing of the semiconductor device 300. Thus, the higher performance or smaller electronic apparatus 400 including the semiconductor device 300 is obtained.

An electronic apparatus according to an embodiment includes a semiconductor device including: a semiconductor substrate, a via formed in the semiconductor substrate, a first transistor of a first channel type which is formed in the semiconductor substrate, which is located in a first lateral direction of the via, and whose channel direction matches the first lateral direction, a second transistor of a second channel type different from the first channel type which is formed in the semiconductor substrate side by side with the first transistor in a second direction perpendicular to the first lateral direction and whose channel direction matches the first direction, an element isolation region which demarcates the first and second transistors, and a stress relaxation region which is formed in the semiconductor substrate, which is located between the via and the first and second transistors, and which is larger than a first part of the element isolation region, the first part being located on a side of the first and second transistors that is opposite to the via.

According to the technique discussed herein, a high-performance semiconductor device including a group of transistors whose characteristics are less varied by the stress generated by a via formed in a semiconductor substrate is obtained. In addition, a high-performance electronic apparatus including the semiconductor device is obtained.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a semiconductor substrate;
a via formed in the semiconductor substrate;
a first transistor of a first channel type which is formed in the semiconductor substrate, which is located in a first lateral direction of the via, and whose channel direction matches the first lateral direction;
a second transistor of the first channel type which is formed in the semiconductor substrate, which is located in the first lateral direction of the via and next to the first transistor sandwiched between the second transistor and the via, and whose channel direction matches the first lateral direction;
a first stress relaxation region which is formed in the semiconductor substrate and which is located between the via and the first transistor; and
a second stress relaxation region which is formed in the semiconductor substrate, which is located between the first and second transistors, and which is smaller than the first stress relaxation region.

2. The semiconductor device according to claim 1, wherein the second stress relaxation region is smaller than the first stress relaxation region in the first lateral direction.

3. The semiconductor device according to claim 1, wherein the second stress relaxation region is smaller than the first stress relaxation region in a thickness direction of the semiconductor substrate.

4. The semiconductor device according to claim 1, wherein the first stress relaxation region includes a first part of an element isolation region which demarcates the first and second transistors.

5. The semiconductor device according to claim 4, wherein the first stress relaxation region further includes a first insulating region formed between the via and the first part.

6. The semiconductor device according to claim 5, wherein the first insulating region is formed of material different from that of the element isolation region.

7. The semiconductor device according to claim 4, wherein the second stress relaxation region includes a second part of the element isolation region.

8. The semiconductor device according to claim 7, wherein the second part includes a third part adjacent to the first transistor and a fourth part separated from the third part and adjacent to the second transistor.

9. The semiconductor device according to claim 8, wherein the second stress relaxation region further includes a second insulating region formed between the third and fourth parts.

10. The semiconductor device according to claim 9, wherein the second insulating region is formed of material different from that of the element isolation region.

11. The semiconductor device according to claim 1 further comprising:
a third transistor of a second channel type different from the first channel type which is formed in the semiconductor substrate, which is formed side by side with the first transistor in a second direction perpendicular to the first lateral direction, which is located next to the first stress relaxation region sandwiched between the via and the third transistor, and whose channel direction matches the first lateral direction; and
a fourth transistor of the second channel type which is formed in the semiconductor substrate, which is formed side by side with the second transistor in the second direction, which is located next to the second stress relaxation region sandwiched between the third and fourth transistors, and whose channel direction matches the first lateral direction.

12. A semiconductor device comprising:
a semiconductor substrate;
a via formed in the semiconductor substrate;
a first transistor of a first channel type which is formed in the semiconductor substrate, which is located in a first lateral direction of the via, and whose channel direction matches the first lateral direction;
a second transistor of a second channel type different from the first channel type which is formed in the semiconductor substrate side by side with the first transistor in a second direction perpendicular to the first lateral direction and whose channel direction matches the first direction;
an element isolation region which demarcates the first and second transistors; and
a stress relaxation region which is formed in the semiconductor substrate, which is located between the via and the first and second transistors, and which is larger than a first part of the element isolation region, the first part being located on a side of the first and second transistors that is opposite to the via.

13. The semiconductor device according to claim 12, wherein the stress relaxation region includes:
a second part of the element isolation region, the second part being located between the via and the first and second transistors; and
an insulating region formed between the via and the second part.

14. An electronic apparatus comprising a semiconductor device including:
a semiconductor substrate,
a via formed in the semiconductor substrate,
a first transistor of a first channel type which is formed in the semiconductor substrate, which is located in a first lateral direction of the via, and whose channel direction matches the first lateral direction,
a second transistor of the first channel type which is formed in the semiconductor substrate, which is located in the first lateral direction of the via and next to the first transistor sandwiched between the second transistor and the via, and whose channel direction matches the first lateral direction,
a first stress relaxation region which is formed in the semiconductor substrate and which is located between the via and the first transistor,
a second stress relaxation region which is formed in the semiconductor substrate, which is located between the first and second transistors, and which is smaller than the first stress relaxation region.
